(19) United States
(12) Patent Application Publication
(10) Pub. No.: US 2025/0393348 A1
(43) Pub. Date: Dec. 25, 2025

(54) LED PACKAGING STRUCTURE AND PROCESS

(71) Applicant: General Lighting Electronic Co., Ltd., Zhongshan (CN)

(72) Inventor: Hai SU, Guilin (CN)

(73) Assignee: General Lighting Electronic Co., Ltd., Zhongshan (CN)

(21) Appl. No.: 18/777,468

(22) Filed: Jul. 18, 2024

(30) Foreign Application Priority Data
Jun. 24, 2024 (CN) 2024108197011

(51) Int. Cl. H01L 33/62; H01L 25/075

(52) U.S. Cl. CPC H10H 20/857; H01L 25/0753; H10H 20/0364

(57) ABSTRACT

The present invention discloses an LED packaging structure and a process, including a support, a chip, positive and negative electrodes, a wire, a fluorescent glue, and a quartz plate with a flat surface, where the support is provided with a bowl cup, the chip is arranged in the bowl cup, the positive and negative electrodes are arranged at the bottom of the bowl cup, the wire correspondingly connects a positive electrode and a negative electrode of the chip to the positive and negative electrodes, the fluorescent glue is potted in the bowl cup to cover the chip and the wire, the quartz plate is connected to the top of the support to seal the bowl cup, and an air separation layer is formed between the quartz plate and a surface of the fluorescent glue.

### CROSS-REFERENCE TO RELATED APPLICATIONS

The application claims priority to Chinese patent application No. 2024108197011, filed on Jun. 24, 2024, the entire contents of which are incorporated herein by reference.

### TECHNICAL FIELD

The present invention relates to the technical field of LED packaging, and in particular, to an LED packaging structure and a process.

### BACKGROUND

An existing LED packaging structure is used in a waterproof lamp. When potting a transparent glue, because the potting glue is directly in contact with a fluorescent glue body packaged by the LED, and a refractive index of the potting glue is inconsistent with a refractive index of air, a propagation path of light on the contact surface is changed, and light of a part of angle cannot enter the interior of the fluorescent glue body for secondary excitation through a total reflection phenomenon. As a result, a light color of the waterproof lamp is severely different from a light color of the used LED, a color temperature rises obviously, color coordinates deviate from a blackbody locus, and color tolerance (SDCM) increases. Therefore, the existing LED packaging structure cannot met the related standard requirements. As shown in FIG. 1, after an existing LED packaging is packaged with a potting glue, an interface on which total reflection occurs is located at the top of the potting glue, and the interface of total reflection is obviously raised, resulting in that reflected light cannot enter the interior of the fluorescent glue body packaged by the LED for secondary excitation, and therefore, photoelectric parameters are greatly changed compared with original lamp beads parameters. Most of the current solutions use a shell structure to waterproof (such as adding a sealing ring, adding a sealant), such a solution not only is not difficult to design, complex in structure, low in assembly efficiency and high in material cost, but also has poor waterproof reliability and low waterproof grade due to internal hollow, which seriously affects the light color effect and service life of the lamp.

### SUMMARY

An objective of the present invention is to at least solve one of the technical problems existing in the prior art, and to provide an LED packaging structure capable of ensuring that a glue-potted light color is consistent with a light color of an LED, and having a simple structure and good waterproof performance.

According to an embodiment of a first aspect of the present invention, an LED packaging structure includes a support, a chip, positive and negative electrodes, a wire, a fluorescent glue, and a quartz plate with a flat surface, where the support is provided with a bowl cup, the chip is arranged in the bowl cup, the positive and negative electrodes are arranged at the bottom of the bowl cup, the wire correspondingly connects a positive electrode and a negative electrode of the chip to the positive and negative electrodes, the fluorescent glue is potted in the bowl cup to cover the chip and the wire, the quartz plate is connected to the top of the support to seal the bowl cup, and an air separation layer is formed between the quartz plate and a surface of the fluorescent glue.

According to some embodiments of the present invention, the quartz plate includes a quartz slide.

According to some embodiments of the present invention, the support is provided with a groove penetrating through the top end face of the support, the groove is arranged around the bowl cup and is in communication with the bowl cup, and the quartz plate is attached to a wall face of the groove.

According to some embodiments of the present invention, the LED packaging structure further includes a potting glue, and the potting glue is packaged outside the support, the quartz plate and the positive and negative electrodes to form an LED packaging body.

According to an embodiment of a second aspect of the present invention, a process is applied to the above LED packaging structure, including:
step 1, dehumidifying: placing the support into an oven for baking to remove moisture on the support;
step 2, wafer expansion: placing a wafer on a wafer expander for expansion,
wherein a spacing between the wafers is equal to a width of ½ to 1 chip;
step 3, die bonding: using a die bonder to fix the chip into the bowl cup via a die bonding glue;
step 4, baking: baking a die bonded semi-finished product to completely cure the die bonding glue;
step 5, cleaning: putting a baked semi-finished product into a cleaning machine to achieve physical and chemical cleaning;
step 6, wire bonding: placing a cleaned semi-finished product into a wire bonder, and connecting the chip and the support into a complete electronic circuit through ultrasonic thermo compression;
step 7, dehumidifying: baking a wire bonded semi-finished product again for dehumidifying;
step 8, cleaning: putting a baked semi-finished product into a cleaning machine to achieve physical and chemical cleaning;
step 9, glue preparation: accurately weighing fluorescent powder and a packaging glue according to a formula standard, and uniformly mixing and stirring the fluorescent powder and the packaging glue to form the fluorescent glue;
step 10, glue dispensing: pouring a prepared fluorescent glue into a bowl cup of the wire bonded semi-finished product through a glue dispenser, so that a surface of the fluorescent glue is lower than an opening of the bowl cup;
step 11, baking: baking a glue dispensed semi-finished product to completely cure the fluorescent glue body;
step 12, attaching the quartz plate: putting the baked semi-finished product into a dedicated ultrasonic attaching machine, so that the support is attached to the quartz plate, and the air separation layer is located between the fluorescent glue body and the quartz slide;
step 13, stripping: placing a product attached with the quartz plate into a corresponding stripping jig for stripping so as to separate same into single LED lamp beads;
step 14, light splitting: placing the single LED lamp beads that have been stripped into a photoelectric testing system to perform 100% photoelectric characteristic sorting; and
step 15, dehumidifying: baking the light split LED lamp beads to remove moisture.

According to the embodiment of the present invention, the LED packaging structure and process have at least the following beneficial effects: a quartz plate with a flat surface is added, so that an air separation layer with a uniform thickness is formed between the surface of the fluorescent glue and the quartz plate. This prevents the potting glue from directly contacting the fluorescent glue when the transparent glue is potted, thereby ensuring the light reflected by the surface of the fluorescent glue to the inside of the fluorescent glue for the second time remains unchanged, and ensuring the total reflection effect. And finally, the light is emitted outwards through the air separation layer with the uniform thickness and the quartz plate with the flat surface, so that the light emission is uniform. A consistent total reflection effect and uniform light emission enable of a glue-potted light color to be consistent with the light color of the LED used, the color temperature does not rise, the color coordinates do not deviate from the blackbody locus, the color tolerance (SDCM) does not increase. Therefore, the present invention can met the related standards and is particularly suitable for white LED lamp beads. Compared with the current solution in which a shell structure is used to waterproof in the prior art, the present invention is simple in structure and convenient to produce, has a low material cost, and facilitates potting of the potting glue. The quartz plate has good sealing performance, and combination of the potting glue and the quartz plate enables the waterproof grade to be high, the reliability is high, the heat dissipation is good, thereby greatly improving the light color effect of the lamp and the service life.

Additional aspects and advantages of the present invention will be given in part in the following descriptions, become apparent in part from the following descriptions, or may be learned from the practice of the present invention.

### BRIEF DESCRIPTION OF THE DRAWINGS

Detailed description of embodiments of the present invention are further described below with reference to the accompanying drawings;

FIG. 1 is a sectional view of an existing LED packaging structure after gluing;

FIG. 2 is a structural diagram of an LED packaging according to an embodiment of the present invention after gluing; and

FIG. 3 is a process flowchart.

### DETAILED DESCRIPTION OF THE EMBODIMENTS

This part will describe the specific embodiments of the disclosure in detail. The preferred embodiments of the disclosure are shown in the accompanying drawings, and the function of the drawings is to supplement the description of the text part with graphics, which enables people to intuitively and vividly understand each technical feature and the overall technical solutions of the disclosure, but cannot be understood as limiting the scope of protection of the disclosure.

In the description of the present invention, it should be understood that the positional descriptions referred to, for example, the directional or positional relationships indicated by up, down, front, rear, left, right, etc., are based on the directional or positional relationships shown in the drawings, and are only for convenience and simplification of description of the disclosure, but not for indicating or implying that the referred device or element must have a specific direction, be constructed and operated in a specific direction, and thus should not be construed as limiting the disclosure.

In the description of the present invention, “several” means one or more, “a plurality of” means more than two, “greater than a number”, “less than a number”, “exceed a number” and the like indicate that the number is excluded, and “above a number”, “below a number”, “within a number”, and the like indicate that the number is included. “First” and “second” are intended only for distinguishing between technical features but cannot be used to indicate or imply relative importance or implicitly specify a quantity of indicated technical features or implicitly specify a sequential relationship of indicated technical features.

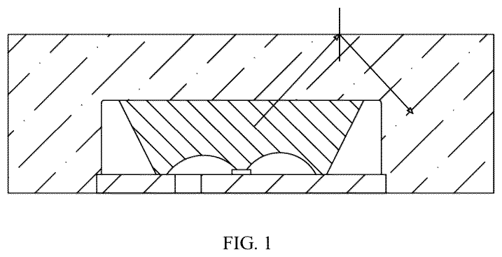

Referring to FIG. 1 to FIG. 3, according to the present invention, an LED packaging structure includes a support 10, a chip 20, positive and negative electrodes 11, a wire 21, a fluorescent glue 30, and a quartz plate 31 with a flat surface, wherein the support 10 is provided with a bowl cup 12, the chip 20 is arranged in the bowl cup 12, the positive and negative electrodes 11 are arranged at the bottom of the bowl cup 12, the wire 21 correspondingly connects a positive electrode and a negative electrode of the chip 20 to the positive and negative electrodes 11, the fluorescent glue 30 is potted in the bowl cup 12 to cover the chip 20 and the wire 21, the quartz plate 31 is connected to the top of the support 10 to seal the bowl cup 12, and an air separation layer 32 is formed between the quartz plate 31 and a surface of the fluorescent glue 30. A quartz plate 31 with a flat surface is added, so that an air separation layer 32 is formed between the surface of the fluorescent glue 30 and the quartz plate 31. This prevents the potting glue from directly contacting the fluorescent glue 30 when the transparent glue is potted, thereby ensuring that the light reflected by the surface of the fluorescent glue 30 to the inside of the fluorescent glue 30 for a second time remains unchanged, and ensuring the total reflection effect. And finally, the light is emitted outwards through the air separation layer with the uniform thickness and the quartz plate with the flat surface, so that the light emission is uniform. Thus, it can be ensured that a glue-potted light color to be consistent with the light color of the LED used, the color temperature does not rise, the color coordinates do not deviate from the blackbody locus, the color tolerance does not increase, and therefore, the present invention can met the related standards and is suitable for white LED lamp beads. Compared with the current solution in which a shell structure is used to waterproof in the prior art, the present invention is simple in structure and convenient to produce, has a low material cost, and facilitates potting of the potting glue. The quartz plate 31 has good sealing performance, and combination of the potting glue and the quartz plate 31 enables the waterproof grade to be high, the reliability is high, the heat dissipation is good, thereby greatly improving the light color effect of the lamp and the service life.

In some embodiments, the quartz plate 31 includes a quartz slide having good flatness, good light transmission effect and good sealing performance.

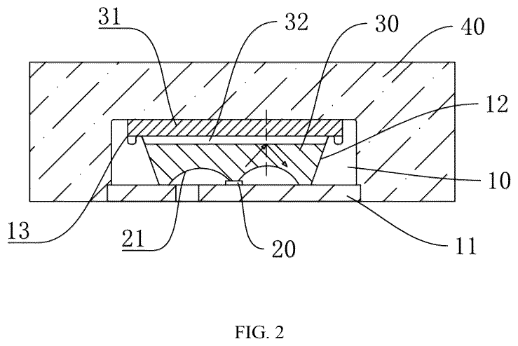

As shown in FIG. 2, the support 10 is provided with a groove 13 penetrating through the top end face of the support 10, the groove 13 is arranged around the bowl cup 12 and is in communication with the bowl cup 12, the quartz plate 31 is attached to the wall face of the groove 13, and the groove 13 facilitates the connection and attachment of the quartz plate 31 and the support 10, thereby improving the overall sealing performance.

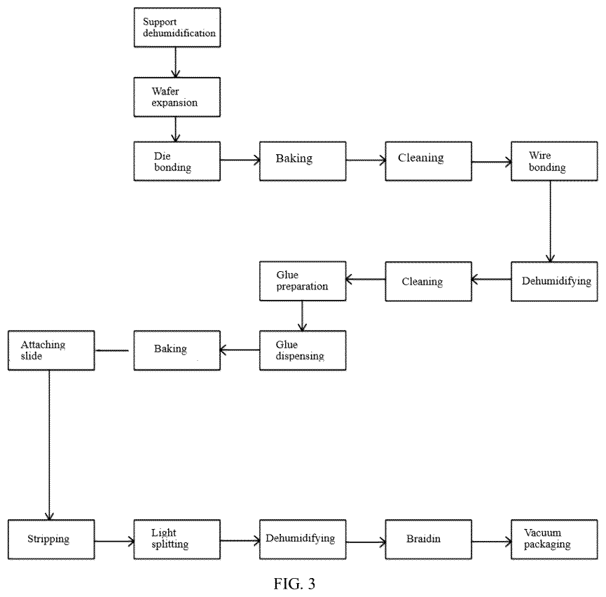

As shown in FIG. 3, the present invention further includes a process for manufacturing the above LED packaging structure, including:
step 1, dehumidifying: placing the support 10 into an oven for baking to remove moisture on the support 10;
step 2, wafer expansion: placing a wafer on a wafer expander for expansion, wherein a spacing between the wafers is equal to a width of ½ to 1 chip 20;
step 3, die bonding: using a die bonder to fix the chip 20 into the bowl cup 12 via a die bonding glue;
step 4, baking: baking a die bonded semi-finished product to completely cure the die bonding glue;
step 5, cleaning: putting a baked semi-finished product into a cleaning machine to achieve physical and chemical cleaning;
step 6, wire bonding: placing a cleaned semi-finished product into a wire bonder, and connecting the chip 20 and the support 10 into a complete electronic circuit through ultrasonic thermo compression;
step 7, dehumidifying: baking a wire bonded semi-finished product again for dehumidifying;
step 8, cleaning: putting a baked semi-finished product into a cleaning machine to achieve physical and chemical cleaning;
step 9, glue preparation: accurately weighing fluorescent powder and a packaging glue according to a formula standard, and uniformly mixing and stirring the fluorescent powder and the packaging glue to form the fluorescent glue 30;
step 10, glue dispensing: pouring a prepared fluorescent glue 30 into a bowl cup 12 of the wire bonded semi-finished product through a glue dispenser, so that a surface of the fluorescent glue 30 is lower than an opening of the bowl cup 12;
step 11, baking: baking a glue dispensed semi-finished product to completely cure the fluorescent glue body 30;
step 12, attaching the quartz plate 31: putting the baked semi-finished product into a dedicated ultrasonic attaching machine, so that the support 10 is attached to the quartz plate 31, and the air separation layer 32 is located between the fluorescent glue body 30 and the quartz slide;
step 13, stripping: placing a product attached with the quartz plate 31 into a corresponding stripping jig for stripping so as to separate same into single LED lamp beads;
step 14, light splitting: placing the single LED lamp beads that have been stripped into a photoelectric testing system to perform 100% photoelectric characteristic sorting; and
step 15, dehumidifying: baking the light split LED lamp beads to remove moisture;
step 16, braiding: placing dehumidified LED lamp beads respectively into an automatic braiding machine for braiding according to a sorted BIN area; and
step 17: vacuum packaging: classifying, labeling, and vacuum packaging the braided product according to requirements.

Further, in the step 1, the support 10 is placed into the oven for baking at 150° C. for one hour; in the step 4, the die bonded semi-finished product is baked at 160° C. for two hours; in the step 7, the wire bonded semi-finished product is baked at 150° C. for one hour; in the step 11, the glue dispensed semi-finished product is baked according to baking conditions of baking at 60° C. for one hour, 100° C. for one hour, and 150° C. for three hours; and in the step 15, the light split LED is baked at 150° C. for one hour. Baking is performed according to the above baking conditions, the baking effect is good, and the product quality is high.

It will be readily understood by those skilled in the art that, on the premise of no conflict, the above preferred embodiments may be freely combined and superimposed.

The foregoing descriptions are only preferred embodiments of the present invention, but are not intended to limit the protection scope of the present invention. Any equivalent structural transformation made by using the description and the accompanying drawings of the present invention, or direct or indirect application of these embodiments to other related technical fields all fall within the protection scope of the present invention.

What is claimed is:

1. An LED packaging structure, comprising:
a support (10), a chip (20), positive and negative electrodes (11), a wire (21), a fluorescent glue (30), and a quartz plate (31) with a flat surface, wherein the support (10) is provided with a bowl cup (12), the chip (20) is arranged in the bowl cup (12), the positive and negative electrodes (11) are arranged at the bottom of the bowl cup (12), the wire (21) correspondingly connects a positive electrode and a negative electrode of the chip (20) to the positive and negative electrodes (11), the fluorescent glue (30) is potted in the bowl cup (12) to cover the chip (20) and the wire (21), the quartz plate (31) is connected to the top of the support (10) to seal the bowl cup (12), and an air separation layer (32) is formed between the quartz plate (31) and a surface of the fluorescent glue (30).

2. The LED packaging structure according to claim 1, wherein the quartz plate (31) comprises a quartz slide.

3. The LED packaging structure according to claim 1, wherein the support (10) is provided with a groove (13) penetrating through the top end face of the support (10), the groove (13) is arranged around the bowl cup (12) and is in communication with the bowl cup (12), and the quartz plate (31) is attached to a wall face of the groove (13).

4. A process, applied to the LED packaging structure according to claim 1, comprising:
step 1, dehumidifying: placing the support (10) into an oven for baking to remove moisture on the support (10);
step 2, wafer expansion: placing a wafer on a wafer expander for expansion, wherein a spacing between the wafers is equal to a width of ½ to 1 chip (20);
step 3, die bonding: using a die bonder to fix the chip (20) into the bowl cup (12) via a die bonding glue;
step 4, baking: baking a die bonded semi-finished product to completely cure the die bonding glue;
step 5, cleaning: putting a baked semi-finished product into a cleaning machine to achieve physical and chemical cleaning;
step 6, wire bonding: placing a cleaned semi-finished product into a wire bonder, and connecting the chip (20) and the support (10) into a complete electronic circuit through ultrasonic thermo compression;
step 7, dehumidifying: baking a wire bonded semi-finished product again for dehumidifying;
step 8, cleaning: putting the baked semi-finished product into a cleaning machine to achieve physical and chemical cleaning;
step 9, glue preparation: accurately weighing fluorescent powder and a packaging glue according to a formula standard, and uniformly mixing and stirring the fluorescent powder and the packaging glue to form the fluorescent glue (30);
step 10, glue dispensing: pouring a prepared fluorescent glue (30) into a bowl cup (12) of the wire bonded semi-finished product through a glue dispenser, so that a surface of the fluorescent glue (30) is lower than an opening of the bowl cup (12);
step 11, baking: baking a glue dispensed semi-finished product to completely cure the fluorescent glue body (30);
step 12, attaching the quartz plate (31): putting the baked semi-finished product into a dedicated ultrasonic attaching machine, so that the support (10) is attached to the quartz plate (31), and the air separation layer (32) is located between the fluorescent glue body (30) and the quartz slide;
step 13, stripping: placing a product attached with the quartz plate (31) into a corresponding stripping jig for stripping so as to separate same into single LED lamp beads;
step 14, light splitting: placing the single LED lamp beads that have been stripped into a photoelectric testing system to perform 100% photoelectric characteristic sorting; and
step 15, dehumidifying: baking the light split LED lamp beads to remove moisture.

5. The process according to claim 4, wherein the process further comprises:
step 16, braiding: placing dehumidified LED lamp beads respectively into an automatic braiding machine for braiding according to a sorted BIN area; and
step 17: vacuum packaging: classifying, labeling, and vacuum packaging the braided product according to requirements.

6. The process according to claim 4, wherein
in the step 1, the support (10) is placed into the oven for baking at 150° C. for one hour;
in the step 4, the die bonded semi-finished product is baked at 160° C. for two hours;
in the step 7, the wire bonded semi-finished product is baked at 150° C. for one hour;
in the step 11, the glue dispensed semi-finished product is baked according to baking conditions of baking at 60° C. for one hour, 100° C. for one hour, and 150° C. for three hours; and
in the step 15, the light split LED is baked at 150° C. for one hour.
